(19) United States
(12) Patent Application Publication
(10) Pub. No.: US 2017/0146852 A1
(43) Pub. Date: May 25, 2017

(54) GLASS SUBSTRATE HAVING BLACK MATRIX, PREPARING METHOD THEREOF AND LIQUID CRYSTAL PANEL

(71) Applicant: Shenzhen China Star Optoelectronics Technology Co., Ltd., Guangdong (CN)

(72) Inventor: Huan LIU, Guangdong (CN)

(73) Assignee: Shenzhen China Star Optoelectronics Technology Co. , Ltd., Shenzhen, Guangdong (CN)

(21) Appl. No.: 14/784,054

(22) PCT Filed: Jun. 24, 2015
(86) PCT No.: PCT/CN2015/082145

§ 371 Date: Oct. 13, 2015

(30) Foreign Application Priority Data
Jun. 16, 2015 (CN) 201510334537.6

(51) Int. Cl. G02F 1/1335; H01L 27/12; G02F 1/1333; G02F 1/1343; G02F 1/1368

(52) U.S. Cl. CPC G02F 1/133512; G02F 1/13439; G02F 1/1368; G02F 1/133345; H01L 27/1262; H01L 27/1218; H01L 27/124; G02F 2001/133302; G02F 2201/121; G02F 2203/01; G02F 2201/123; G02F 2001/136222

(57) ABSTRACT

A glass substrate having a black matrix which includes a glass substrate and a black matrix array formed on the glass substrate, wherein the thickness of the black matrix gradually decreases from the middle to both ends is disclosed. The preparing method of the glass substrate includes S101, providing a glass substrate and forming a black matrix thin film layer on the glass substrate; and S102, performing an exposure process and a developing process on the black matrix thin film layer to obtain the black matrix array; wherein an exposure mask corresponds to an exposure region of each black matrix during performing the exposure process, and the exposure amount thereof gradually decreases from the middle to both ends. A liquid crystal panel which includes the above mentioned glass substrate and integrates a color filter into a thin film transistor array substrate (color filter on array) is also disclosed.

### TECHNICAL FIELD

The disclosure relates to a liquid crystal display technical field, especially to a liquid crystal panel which integrates a color filter into a thin film transistor array substrate (Color filter on array, COA), and particularly to a glass substrate having a black matrix in the liquid crystal panel and a preparing method thereof.

### BACKGROUND ART

A Liquid Crystal Display (LCD) is a display apparatus of which the panel is ultra-thin, which is composed of a certain amount of colorful or black-and-white pixels and disposed in front of a light source or a reflection plate. The liquid crystal display enjoys its popularity and becomes a mainstream of the display due to its low power consumption, high-definition, small in size and light-weight, etc. The main current liquid crystal display is the Thin Film Transistor (TFT).

The reason why a TFT-LCD is developed rapidly is more associated with a base of amorphous silicon platform (a small part of products certainly use polysilicon), which has a cheap price, simple process and better uniformity, hence, products with a large size, such as 55 inches and 65 inches, etc have been manufactured recently. When a size of a liquid crystal panel becomes large, impedance of the circuit increases, and then it needs a bolder, thicker or better conductivity metal wiring. Since the thickness cannot unlimitedly increase, and the material having the best conductivity is metallic silver and cooper in the present time, it is estimated that there will be no breakthrough for a better practicable conductive material for a long time, only a line width can increase, such that aperture ratio of the TFT-LCD is further lowered.

For the disadvantage of low aperture ratio in the TFT-LCD, there are many solutions from a technical standpoint to solve such problem, for example, using a metal wire with lower impedance, using a more challenging design solution, and using some new liquid crystal display modes. One of them is to integrate a color filter into a thin film transistor array substrate (Color filter on array, COA). A liquid crystal panel using a COA technology as shown in FIG. 1 includes an upper glass substrate 10, a lower glass substrate 20 and a liquid crystal layer 30 interposed between the upper glass substrate 10 and the lower glass substrate 20. One side of the lower glass substrate 20 closing to the liquid crystal layer 30 is disposed with a plurality of thin film transistors 201, each of which is correspondingly connected to a pixel electrode 205 on which a transparent passivation layer is generally disposed. Since the COA technology is adopted, a color filter 203 is further disposed between the thin film transistor 201 and the pixel electrode 205, and the color filter 203 includes a red filter unit 203R, a green filter unit 203G and a blue filter unit 203B, wherein each of pixel electrodes 205 corresponds to a red filter unit 203R, a green filter unit 203G or a blue filter unit 203B. The thin film transistor 201 and the color filter 203 are insulated by a first insulating protective layer 202, and the color filter 203 and the pixel electrode 205 are insulated by a second insulating protective layer 204. A Black Matrix (BM) 101a array is disposed on one side of the upper glass substrate 10 closing to the liquid crystal layer 30, each black matrix corresponding to an adjacent region of two of filter units 203R, 203G and 203B, to prevent light leakage. Generally, the black matrix 101a array is covered with an ITO common electrode 102 thereon. With respect to a traditional liquid crystal panel, a problem that a color filter unit is not strictly aligning with a pixel electrode does not exist in a liquid crystal panel adopting a COA technology. Hence, the aperture ratio of the liquid crystal panel may be improved.

A black matrix array is generally obtained using a photoetching process, in a negative photoetching process, a black matrix thin film layer is first coated on the substrate; an exposure mask is then disposed on the black matrix thin film layer for exposure, in an exposure region, the black matrix thin film layer is irradiated by the light to be solidified; finally, an unexposed region in the black matrix thin film layer is develop-removed, and a solidified part of the black matrix thin film layer is left to form a black matrix array. In the prior art, an ordinary exposure mask is adopted to expose the black matrix thin film layer, an edge of the obtained black matrix generally forms a taper angle, as shown in FIG. 2, an angle α between the top and the side of the black matrix 101a is approximate 90°. In an region closing to the black matrix 101a in the liquid crystal layer 30, liquid crystal molecules 301 are inclined to be perpendicular to a surface of the black matrix 101a, while since the angle α between the top and the side of the black matrix 101a is approximate 90°, a part of liquid crystal molecules 301 are perpendicular to the side of the black matrix 101a, resulting in confused arrangement of the liquid crystal molecules 301 in the region, which lowers light transmittance of the product, and finally reflects in darkstripe on pixel edges in the display of the liquid crystal panel, thereby affecting display quality of the liquid crystal panel.

In order to improve the problem on darkstripe generated on pixel edges caused by the above structure of the black matrix 101a, a current method is covering a flat layer on the black matrix 101a array. But this method increases a process of preparing a flat layer, and aperture ratio of the liquid crystal panel would be lowered after disposing a flat layer, which is not beneficial to reducing cost of the product and improving quality of the product.

### SUMMARY

In consideration of insufficiency of the prior art, the present disclosure provides a glass substrate having a black matrix which is mainly applied to a liquid crystal panel of integrating a color filter into a thin film transistor array substrate (Color filter on array, COA), which solves the defect of darkstripe on pixel edges caused due to a black matrix having a taper angle on an edge thereof in the prior art.

In order to achieve the above purpose, the present disclosure adopts the following technical solution:

A glass substrate having a black matrix includes a glass substrate and a black matrix array formed on the glass substrate, wherein the thickness of the black matrix gradually decreases from the middle to both ends.

The thickness of the black matrix may continuously and gradually decrease from the middle to both ends.

The present disclosure further provides a method for preparing the above glass substrate having a black matrix, which includes: S101, providing a glass substrate and forming a black matrix thin film layer on the glass substrate; S102, performing an exposure process and a developing process on the black matrix thin film layer to obtain the black matrix array; wherein an exposure mask corresponds to an exposure region of each black matrix during performing the exposure process, and the exposure amount thereof gradually decreases from the middle to both ends.

The exposure region may be sequentially divided into from first to nth regions from the middle to both ends, wherein light intensities of exposure light sources that the first to nth regions correspond to gradually decrease, and n is an integer larger than 1.

The light intensity of the exposure light source of the nth region may be 40% of the light intensity of the exposure light source of the first region, and light intensities of exposure light sources that the first to nth regions correspond to gradually decrease by equal difference.

The exposure region may be sequentially divided into from first to nth regions from the middle to both ends, wherein the first to nth regions include light transmittance materials having different light transmittances, the light transmittances of the light transmittance materials that the first to nth regions correspond to gradually decrease, and n is an integer larger than 1.

The light transmittance of the light transmittance material of the nth region may be 40% of the light transmittance of the light transmittance material of the first region, and the light transmittances of the light transmittance materials that the first to nth regions correspond to gradually decrease.

The exposure region may be sequentially divided into from first to nth regions from the middle to both ends, wherein the first to nth regions include light transmittance portions and non-light transmittance portions, the areas of the light transmittance portions that the first to nth regions correspond to gradually decrease, and n is an integer larger than 1.

The area of the light transmittance portion of the nth region may be 40% of the area of the light transmittance portion of the first region, and the areas of the light transmittance portions that the first to nth regions correspond to gradually decrease by equal difference.

Another aspect of the present disclosure provides a liquid crystal panel which includes first and second glass substrates oppositely disposed and a liquid crystal layer positioned between the first glass substrate and the second glass substrate, wherein the first glass substrate is the above-mentioned glass substrate having a black matrix, and the second glass substrate is a thin film transistor array substrate having a color filter.

In the COA liquid crystal panel provided by the embodiments of the present disclosure, the thickness of each black matrix in the glass substrate having a black matrix gradually decreases from the middle to both ends, the edge of the black matrix is not a taper angle shape any more, and there is little difference between the arrangement of liquid crystal molecules in an region of the liquid crystal layer closing to the black matrix and the arrangement of liquid crystal molecules outside the region, which effectively reduces darkstripe generated on pixel edges. The present disclosure is to improve a shape of a black matrix during the process of preparing a black matrix without additionally increasing a structural layer on a glass substrate, which does not increase the cost of the product while improving display quality of a liquid crystal panel.

### BRIEF DESCRIPTION OF THE DRAWINGS

FIG. 1 is a structure diagram of a current COA liquid crystal panel.

FIG. 2 is a local enlargement diagram of an A part in FIG. 1.

FIG. 3 is a structure diagram of the COA liquid crystal panel in embodiments of the present disclosure.

FIG. 4 is a local enlargement diagram of a B part in FIG. 3.

FIG. 5 is a flow chart of a preparing process of a glass substrate having a black matrix in embodiments of the present disclosure.

FIGS. 6a to 6d are diagrams of a preparing process of a glass substrate having a black matrix in embodiments of the present disclosure.

FIG. 7 is a sample diagram of implementing a change in exposure amount in one embodiment of the present disclosure.

FIG. 8 is a sample diagram of implementing a change in exposure amount in another embodiment of the present disclosure.

FIG. 9 is a sample diagram of implementing a change in exposure amount in another embodiment of the present disclosure.

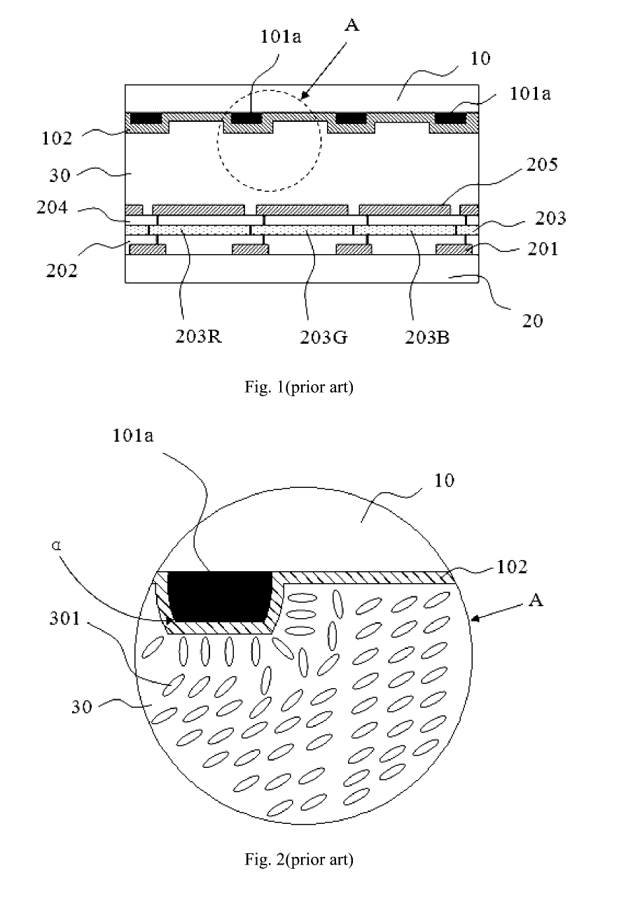

### DETAILED DESCRIPTION OF EXEMPLARY EMBODIMENTS

As previously mentioned, the present disclosure provides a glass substrate having a black matrix which includes a glass substrate and a black matrix array formed on the glass substrate directed at a COA liquid crystal panel in the prior art which has a defect of darkstripe on pixel edges caused due to a black matrix having a taper angle on an edge thereof, wherein the thickness of the black matrix gradually decreases from the middle to both ends. The edge of the black matrix is not a taper angle shape any more by improving a shape of the black matrix, and there is little difference between the arrangement of liquid crystal molecules in an region of the liquid crystal layer closing to the black matrix and the arrangement of liquid crystal molecules outside the region, which solves the problem of darkstripe on pixel edges caused due to a black matrix having a taper angle on an edge thereof.

Hereinafter, the technical solutions in exemplary embodiments of the present disclosure are described in detail in conjunction with the accompanying drawings and detailed embodiments, and it is apparent that the described embodiments are only a part of exemplary embodiments of the present disclosure rather than all of the exemplary embodiments. Based on the embodiments of the present disclosure, all of the other embodiments obtained by those ordinarily skilled in the art without exerting creative labor fall within the protection scope of the present disclosure.

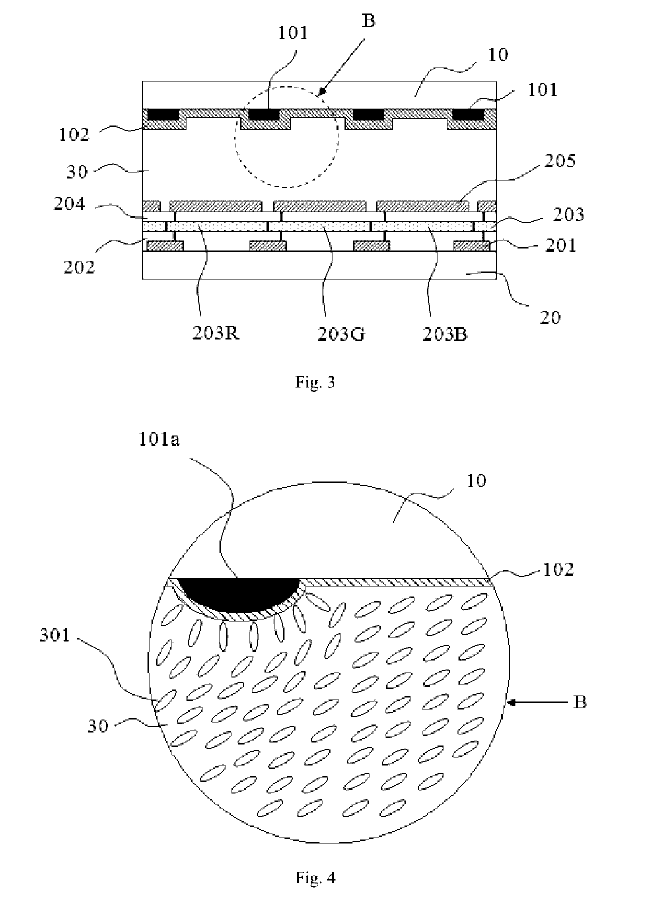

Referring to FIG. 3, the present embodiment provides a liquid crystal panel using a COA technology which includes a first glass substrate 10, a second glass substrate 20 and a liquid crystal layer 30 between the first glass substrate 10 and the second glass substrate 20, wherein the first glass substrate 10 is the above-mentioned glass substrate having a black matrix, and the second glass substrate 20 is a thin film transistor array substrate having a color filter.

Particularly, as shown in FIG. 3, one side of the second glass substrate 20 closing to the liquid crystal layer 30 is disposed with a plurality of thin film transistors 201, each of which is correspondingly connected to a pixel electrode 205 on which a transparent passivation layer is generally disposed. Since the COA technology is adopted, a color filter 203 is further disposed between the thin film transistor 201 and the pixel electrode 205, the color filter 203 includes a red filter unit 203R, a green filter unit 203G and a blue filter unit 203B; wherein each of pixel electrodes 205 corresponds to a red filter unit 203R, a green filter unit 203G or a blue filter unit 203B, respectively. Wherein the thin film transistor 201 and the color filter 203 are insulated by a first insulating protective layer 202, and the color filter 203 and the pixel electrode 205 are insulated by a second insulating protective layer 204. One side of the first glass substrate 10 closing to the liquid crystal layer 30 is disposed with a black matrix 101a array, each black matrix 101 is corresponding to an adjacent region of two filter units 203R, 203G and 203B, respectively, to prevent leakage of light. Furthermore, the black matrix 101a array is covered with an ITO common electrode 102.

Different from the prior art, in the first glass substrate 10 provided by the embodiments of the present disclosure, a shape of the black matrix 101 therein is improved, as shown in FIG. 4, the thickness of the black matrix 101a formed on the first glass substrate 10 gradually decreases from the middle to both ends. Particularly, the thickness of the black matrix 101 continuously, slightly and gradually decreases from the middle to both ends. In an region closing to the black matrix 101 in the liquid crystal layer 30, liquid crystal molecules 301 are inclined to be perpendicular to a surface of the black matrix 101, but since the surface of the black matrix 101 is continuously and slightly lowered, there is little difference between the arrangement of liquid crystal molecules 301 in an region of the liquid crystal layer 30 closing to the black matrix 101 and the arrangement of liquid crystal molecules 301 outside the region (there are little liquid crystal molecules 301 having a large arrangement difference), which effectively reduce darkstripe generated on pixel edges caused by confused arrangement of liquid crystal molecules 301.

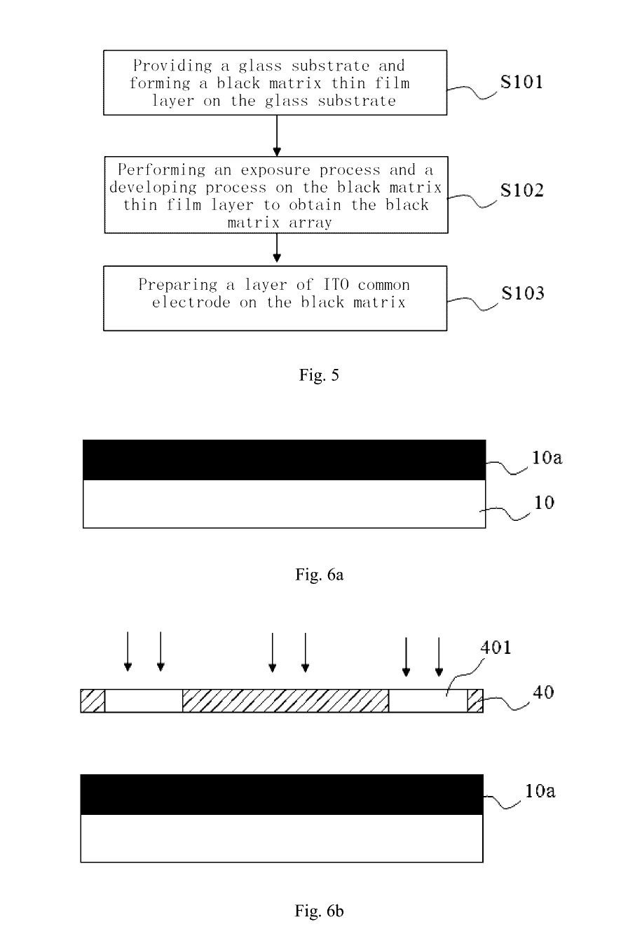

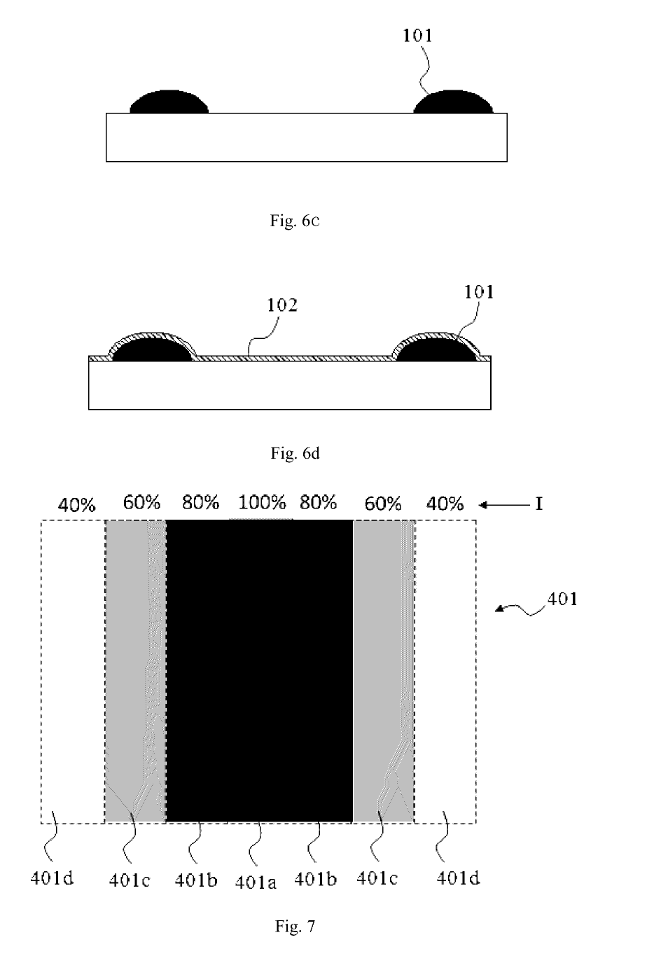

A preparing method of the first glass substrate 10 having the above mentioned black matrix 101 will be introduced below. Referring to FIGS. 5 and 6a to 6d, the preparing method includes:

S101, providing a glass substrate 10 and forming a black matrix thin film layer 10a on the glass substrate 10, as shown in FIG. 6a.

S102, performing an exposure process and a developing process on the black matrix thin film layer 10a to obtain the black matrix 101 array. Wherein an exposure mask 40 corresponds to an exposure region 401 of each black matrix 101 during performing the exposure process, and the exposure amount thereof gradually decreases from the middle to both ends, as shown in FIGS. 6b and 6c.

S103, preparing a layer of ITO common electrode 102 on the black matrix 101, as shown in FIG. 6d.

When performing the exposure process, the exposure region 401 of the exposure mask 40 may be sequentially divided into from first to nth regions from the middle to both ends, and exposure amounts of the first to nth regions gradually decrease, wherein n is an integer larger than 1. Taking n=4 as an example, some manners for implementing gradually decreasing of exposure amounts of the first to nth regions are introduced as follows:

The first method: Referring to FIG. 7, the middle of the exposure region 401 is first set as a first region 401a, there are sequentially a second region 401b, a third region 401c and a fourth region 401d from the first region 401a to one end of the exposure region 401, and there are sequentially a second region 401b, a third region 401c and a fourth region 401d from the first region 401a to another end of the exposure region 401. Each of the first region 401a, the second region 401b, the third region 401c and the fourth region 401d has the same exposure area and light transmittance. Then, exposure light sources having different light intensities I are provided to the first region 401a, the second region 401b, the third region 401c and the fourth region 401d, respectively. Specific to the present embodiment, the light intensity I of the exposure light source of the first region 401a is set as 100%, then the light intensity I of the exposure light source of the second region 401b is 80%, the light intensity I of the exposure light source of the third region 401c is 60% and the light intensity I of the exposure light source of the fourth region 401d is 40%. In the above manner, although the exposure amounts ladder-decrease, the finally obtained black matrix 101 does not present an apparent ladder shape due to dispersion of light and mutual function of the black matrix thin film layer during the exposure but present a shape of lowering evenly, slowly and gradually. It needs to be explained that in other embodiments, for example, the value of n is not 4, then the light intensity I of the exposure light source of the first region 401a is 100%, the light intensity I of the exposure light source of the nth region is 40% of the light intensity I of the exposure light source of the first region, and light intensities I of exposure light sources that the first to nth regions correspond to gradually decrease by equal difference.

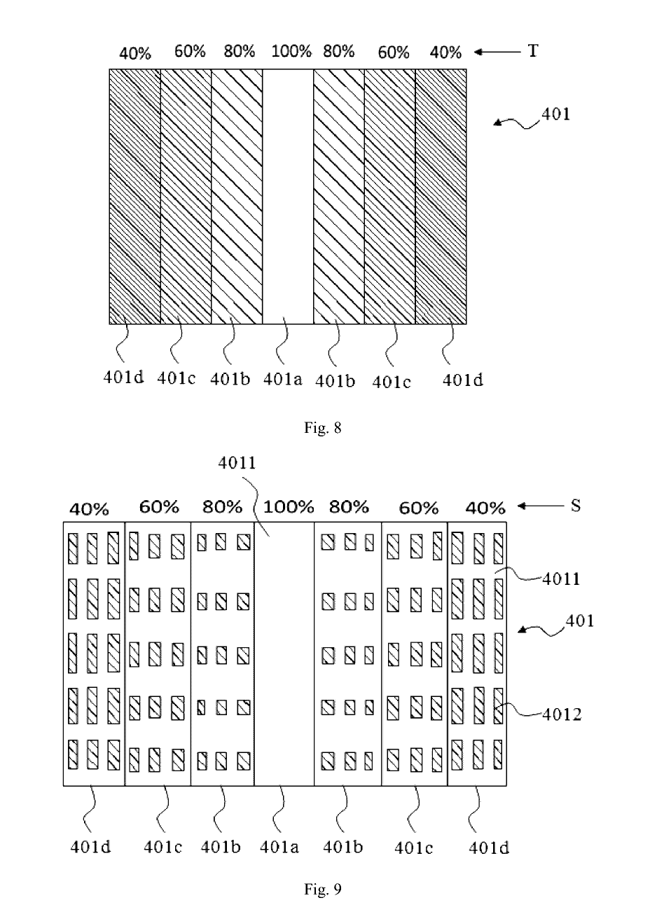

The second method: Referring to FIG. 8, the middle of the exposure region 401 is first set as a first region 401a, there are sequentially a second region 401b, a third region 401c and a fourth region 401d from the first region 401a to one end of the exposure region 401, and there are sequentially a second region 401b, a third region 401c and a fourth region 401d from the first region 401a to another end of the exposure region 401. Each of the first region 401a, the second region 401b, the third region 401c and the fourth region 401d has the same exposure area and uses the exposure light source having the same light intensity. In the manner, different regions include light transmittance materials having different light transmittances T. Specific to the present embodiment, the light transmittance T of the light transmittance material of the first region 401a is set as 100%, then the light transmittance T of the light transmittance material of the second region 401b is 80%, the light transmittance T of the light transmittance material of the third region 401c is 60% and the light transmittance T of the light transmittance material of the fourth region 401d is 40%. In the above manner, although the exposure amounts ladder-decrease, the finally obtained black matrix 101 does not present an apparent ladder shape due to dispersion of light and mutual function of the black matrix thin film layer during the exposure but present a shape of lowering evenly, slowly and gradually. It needs to be explained that in other embodiments, for example, the value of n is not 4, then the light transmittance T of the light transmittance material of the first region 401a is 100%, the light transmittance T of the light transmittance material of the nth region is 40% of the light transmittance T of the light transmittance material of the first region, and light transmittances T of the light transmittance materials that the first to nth regions correspond to gradually decrease by equal difference.

The third method: Referring to FIG. 9, the middle of the exposure region 401 is first set as a first region 401a, there are sequentially a second region 401b, a third region 401c and a fourth region 401d from the first region 401a to one end of the exposure region 401, and there are sequentially a second region 401b, a third region 401c and a fourth region 401d from the first region 401a to another end of the exposure region 401, each of the first region 401a, the second region 401b, the third region 401c and the fourth region 401d includes a light transmittance portion 4011 and a non-light transmittance portion 4012 (the first region 401a may be all a light transmittance portion 4011), respectively, wherein the light transmittance portion 4011 in each of the regions has the same light transmittance and each of the regions uses the exposure light source having the same light intensity. In the manner, the exposure amount is mainly controlled by setting an area S (exposure area) of the light transmittance portion 4011. Specific to the present embodiment, the area S of the light transmittance portion 4011 of the first region 401a is set as 100%, then the area S of the light transmittance portion 4011 of the second region 401b is 80%, the area S of the light transmittance portion 4011 of the third region 401c is 60% and the area S of the light transmittance portion 4011 of the fourth region 401d is 40%. In the above manner, although the exposure amounts ladder-decrease, the finally obtained black matrix 101 does not present an apparent ladder shape due to dispersion of light and mutual function of the black matrix thin film layer during the exposure but present a shape of lowering evenly, slowly and gradually. It needs to be explained that in other embodiments, for example, the value of n is not 4, then the area S of the light transmittance portion 4011 of the first region 401a is 100%, the area S of the light transmittance portion 4011 of the nth region is 40% of the area S of the light transmittance portion 4011 of the first region, and regions S of the light transmittance portions 4011 that the first to nth regions correspond to gradually decrease by equal difference.

To sum up, in the COA liquid crystal panel provided by the embodiments of the present disclosure, the thickness of each black matrix in the glass substrate having a black matrix gradually decreases from the middle to both ends, the edge of the black matrix is not a taper angle shape any more, and there is little difference between the arrangement of liquid crystal molecules in an region of the liquid crystal layer closing to the black matrix and the arrangement of liquid crystal molecules outside the region, which effectively reduces darkstripe generated on pixel edges. The present disclosure is to improve a shape of a black matrix during the process of preparing a black matrix without additionally increasing a structural layer on a glass substrate, which does not increase the cost of the product while improving display quality of a liquid crystal panel.

It should be explained that the relationship terms, such as first and second, etc., in the present text are only used for distinguishing one entity or operation from another entity or operation without requiring or implying any actual relation or sequence existing between these entities or operations. Moreover, the term “include”, “contain” or any other variant means covering instead of exclusively including, so that the process, method, object or device including a series of factors not only includes those factors but also includes other factors that are not explicitly listed or further include inherent factors for this process, method, object or device. Where no more limitations are provided, the factors defined by the sentence “include one . . . ” do not exclude additional identical factors existing in the process, method, object or device which includes the factors.

The above statements are only the specific embodiments of the present application, it should be pointed out that, to those ordinary skilled in the art, several improvements and polish can be made without breaking away from the principle of the present application, also those improvements and polish should be considered as the protection scope of the present application.

1. A glass substrate having a black matrix, comprising a glass substrate and a black matrix array formed on the glass substrate, wherein the thickness of the black matrix gradually decreases from the middle to both ends.

2. The glass substrate having a black matrix of claim 1, wherein the thickness of the black matrix continuously and gradually decreases from the middle to both ends.

3. The glass substrate having a black matrix of claim 1, wherein the black matrix array is further provided with a layer of ITO common electrode.

4. A method for preparing a glass substrate having a black matrix, wherein the glass substrate having a black matrix comprises a glass substrate and a black matrix array formed on the glass substrate, and the thickness of the black matrix gradually decreases from the middle to both ends; the preparing method thereof comprising:
S101, providing a glass substrate and forming a black matrix thin film layer on the glass substrate; and
S102, performing an exposure process and a developing process on the black matrix thin film layer to obtain the black matrix array; wherein an exposure mask corresponds to an exposure region of each black matrix during performing the exposure process, and the exposure amount thereof gradually decreases from the middle to both ends.

5. The method for preparing a glass substrate having a black matrix of claim 4, wherein the exposure region is sequentially divided into from first to nth regions from the middle to both ends, wherein light intensities of exposure light sources that the first to nth regions correspond to gradually decrease, and n is an integer larger than 1.

6. The method for preparing a glass substrate having a black matrix of claim 5, wherein the light intensity of the exposure light source of the nth region is 40% of the light intensity of the exposure light source of the first region, and light intensities of exposure light sources that the first to nth regions correspond to gradually decrease by equal difference.

7. The method for preparing a glass substrate having a black matrix of claim 4, wherein the exposure region is sequentially divided into from first to nth regions from the middle to both ends, wherein the first to nth regions comprise light transmittance materials having different light transmittances, the light transmittances of the light transmittance materials that the first to nth regions correspond to gradually decrease, and n is an integer larger than 1.

8. The method for preparing a glass substrate having a black matrix of claim 5, wherein the light transmittance of the light transmittance material of the nth region is 40% of the light transmittance of the light transmittance material of the first region, and the light transmittances of the light transmittance materials that the first to nth regions correspond to gradually decrease by equal difference.

9. The method for preparing a glass substrate having a black matrix of claim 4, wherein the exposure region is sequentially divided into from first to nth regions from the middle to both ends, wherein the first to nth regions comprise light transmittance portions and non-light transmittance portions, the areas of the light transmittance portions that the first to nth regions correspond to gradually decrease, and n is an integer larger than 1.

10. The method for preparing a glass substrate having a black matrix of claim 5, wherein the area of the light transmittance portion of the nth region is 40% of the area of the light transmittance portion of the first region, and the areas of the light transmittance portions that the first to nth regions correspond to gradually decrease by equal difference.

11. The method for preparing a glass substrate having a black matrix of claim 3, wherein the method further comprises S103, preparing a layer of ITO common electrode on the black matrix array.

12. The method for preparing a glass substrate having a black matrix of claim 3, wherein the thickness of the black matrix continuously and gradually decreases from the middle to both ends.

13. A liquid crystal panel, comprising a first glass substrate and a second glass substrate which are oppositely disposed and a liquid crystal layer positioned between the first glass substrate and the second glass substrate, wherein the first glass substrate is a glass substrate having a black matrix, which comprises a glass substrate and a black matrix array formed on the glass substrate, and the thickness of the black matrix gradually decreases from the middle to both ends; and the second glass substrate is a thin film transistor array substrate having a color filter.

14. The liquid crystal panel of claim 13, wherein the thickness of the black matrix continuously and gradually decreases from the middle to both ends.

15. The liquid crystal panel of claim 13, wherein the black matrix array is further provided with a layer of ITO common electrode.

16. The liquid crystal panel of claim 13, wherein one side of the second glass substrate closing to the liquid crystal layer is disposed with a plurality of thin film transistors, each of which is correspondingly connected to a pixel electrode; a color filter is disposed between the thin film transistor and the pixel electrode, and the color filter comprises a red filter unit, a green filter unit and a blue filter unit; wherein each of pixel electrodes corresponds to a red filter unit, a green filter unit or a blue filter unit, respectively; each black matrix in the first glass substrate corresponds to an adjacent region of two filter units, respectively.

17. The liquid crystal panel of claim 16, wherein the thin film transistor and the color filter are insulated by a first insulating protective layer, and the color filter and the pixel electrode are insulated by a second insulating protective layer.
